(19) United States
(12) Patent Application Publication
(10) Pub. No.: US 2024/0155922 A1
(43) Pub. Date: May 9, 2024

(54) DISPLAY DEVICE

(71) Applicant: LG Display Co., Ltd., Seoul (KR)

(72) Inventors: GiSang HONG, Seoul (KR); SungKi KIM, Gyeonggi-do (KR); JongWon LEE, Seoul (KR); YoungWook LEE, Gyeonggi-do (KR); Jungmin KIM, Gyeonggi-do (KR); Hoseung LEE, Gyeonggi-do (KR)

(21) Appl. No.: 18/484,162

(22) Filed: Oct. 10, 2023

(30) Foreign Application Priority Data
Nov. 7, 2022 (KR) 10-2022-0146718

(51) Int. Cl. H10K 59/80; G09G 3/3233; H10K 59/122; H10K 59/131; H10K 59/88

(52) U.S. Cl. CPC H10K 59/878; G09G 3/3233; H10K 59/122; H10K 59/131; H10K 59/88; G09G 2300/0842

(57) ABSTRACT

Embodiments of the disclosure relate to a display device. Specifically, there may be provided a display device capable of enhancing light extraction efficiency by reducing the distance between the organic light emitting layer and the side reflection layer by comprising a substrate including a plurality of subpixels, an overcoat layer disposed on the substrate and having a recess positioned between the subpixels, a first electrode disposed to cover an upper surface of the overcoat layer and an inclined surface of the recess and including a transparent conductive material, a reflection layer disposed on the first electrode on the inclined surface of the recess and including a metal or metal alloy, and a bank layer positioned in the recess and disposed on the reflection layer.

### CROSS-REFERENCE TO RELATED APPLICATION

This application claims priority from Korean Patent Application No. 10-2022-0146718, filed on Nov. 7, 2022, which is hereby incorporated by reference for all purposes as if fully set forth herein.

### BACKGROUND

### Technical Field

Embodiments of the disclosure relate to a display device.

### Description of the Related Art

Display devices are widely used as display screens for laptop computers, tablet computers, smartphones, portable display devices, and portable information devices, as well as for televisions or monitors.

Display devices may be divided into reflective display devices and emissive display devices. The reflective display device is a display device that displays information by reflecting natural light or light from an external light source of the display device to the display device. The emissive display device displays information using the light generated from light emitting elements or a light source embedded in the display device.

### BRIEF SUMMARY

In the conventional display device, the light emitted from the organic light emitting layer and traveling to the side disappears at the bank layer without being extracted to the outside because of a second electrode, which results in reducing light efficiency. Further, reflection of external light may deteriorate visibility and contrast ratio.

Embodiments of the disclosure may provide a display device capable of enhancing light extraction efficiency by reducing the distance between the organic light emitting layer and the side reflection layer by applying a multi-layer structure in which a first electrode formed of a transparent conductive material is disposed in the opening area, and the first electrode and a reflection layer on the first electrode are disposed in the bank layer area.

Embodiments of the disclosure may provide a display device capable of protecting the active layer of the thin film transistor from the light emitted from the organic light emitting layer by applying a multi-layer structure of a first electrode and a reflection layer.

Embodiments of the disclosure may provide a display device capable of reducing damage to the cathode electrode and progressive dark spot defect rate due to a laser beam during repair by applying a multi-layer structure of a first electrode and a reflection layer.

Embodiments of the disclosure may provide a display device capable of reducing the area where a clock line portion is formed in the bezel area by applying a multi-layer structure of a first electrode and a reflection layer and disposing clock lines on different layers.

Embodiments of the disclosure may provide a display device comprising a substrate including a plurality of subpixels, an overcoat layer disposed on the substrate and having a recess positioned between the subpixels, a first electrode disposed to cover an upper surface of the overcoat layer and an inclined surface of the recess and including a transparent conductive material, a reflection layer disposed on the first electrode on the inclined surface of the recess and including a metal or metal alloy, and a bank layer positioned in the recess and disposed on the reflection layer.

Embodiments of the disclosure may provide a display device comprising a substrate including a display area including a subpixel and a non-display area surrounding the display area, an overcoat layer disposed on the substrate and including an upper surface having an X zone and a Z zone and an inclined surface having a Y zone adjacent to the Z zone, an organic light emitting element disposed in the X zone and including a first electrode, an organic light emitting layer, and a second electrode, and a reflection layer disposed in a portion of the Z zone and the Y zone, wherein emission widths of the X, Y, and Z zones produced as the subpixel emits light on a plane have a relationship of X zone>Y zone>Z zone.

Embodiments of the disclosure may provide a display device comprising a plurality of subpixels including an emission area and a non-emission area and a substrate where a bank layer defining an opening of each of the plurality of subpixels is disposed, wherein the emission area includes a first overcoat layer disposed on the substrate, a second overcoat layer positioned in an area corresponding to the opening and disposed on the first overcoat layer, and a first electrode disposed on the second overcoat layer, and wherein the non-emission area includes a thin film transistor disposed on the substrate, the first overcoat layer disposed on the thin film transistor, the first electrode disposed on the first overcoat layer, and a reflection layer disposed on the first electrode.

Embodiments of the disclosure may provide a display device, wherein the non-emission area includes a clock line portion including first clock lines and second clock lines disposed on different layers, and wherein the second clock lines are multi-layer lines of the first electrode and the reflection layer disposed on the first electrode.

Embodiments of the disclosure may provide a display device, wherein the non-emission area includes a repair line disposed on the substrate, the first overcoat layer disposed on the repair line and including a contact hole, the first electrode disposed in the contact hole, and the reflection layer disposed on the first electrode, and wherein at least one insulation layer is disposed between the repair line and the first electrode.

According to embodiments of the disclosure, there may be provided a display device capable of enhancing light extraction efficiency by reducing the distance between the organic light emitting layer and the side reflection layer.

According to embodiments of the disclosure, there may be provided a display device capable of protecting the active layer of the thin film transistor from the light emitted from the organic light emitting layer.

According to embodiments of the disclosure, there may be provided a display device capable of reducing damage to the cathode electrode and progressive dark spot defect rate due to a laser beam during repair.

According to the embodiments of the disclosure, there may be provided a display device capable of reducing the area where a clock line portion is formed in the bezel area.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view schematically illustrating a system configuration of a display device according to embodiments of the disclosure;

FIG. 2 is a view illustrating a schematic planar structure of a pixel structure disposed on a display panel of a display device according to embodiments of the disclosure;

FIG. 3 is a cross-sectional view illustrating an example structure, taken along line A-A′ of FIG. 2;

FIG. 4 is an enlarged view illustrating a cross-sectional structure of portion Z of FIG. 3;

FIG. 5 is a cross-sectional view illustrating another example structure, taken along line A-A′ of FIG. 2;

FIGS. 6A, 6B, 6C, and 6D are views illustrating a process of forming a display panel according to embodiments of the disclosure;

FIG. 7 is a view illustrating an emission area and a non-emission area of a subpixel in a display device according to embodiments of the disclosure;

FIG. 8A is a view illustrating a schematic planar structure of a bezel area to which a structure according to embodiments of the disclosure is not applied;

FIG. 8B is a view illustrating a schematic planar structure of a bezel area to which a structure according to embodiments of the disclosure is applied;

FIG. 8C is a view illustrating a schematic planar structure of a bezel area for comparing the bezel area shown in FIG. 8A with the bezel area shown in FIG. 8B;

FIG. 9 is a view illustrating a schematic cross-sectional structure of a display panel to which a structure according to embodiments of the disclosure is not applied;

FIG. 10 is a view illustrating a schematic cross-sectional structure of a display panel to which a structure according to embodiments of the disclosure is applied; and

FIG. 11 is a view illustrating a schematic cross-sectional structure of a display panel to which a structure according to other embodiments of the disclosure is applied.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the disclosure are described in detail with reference to the accompanying drawings.

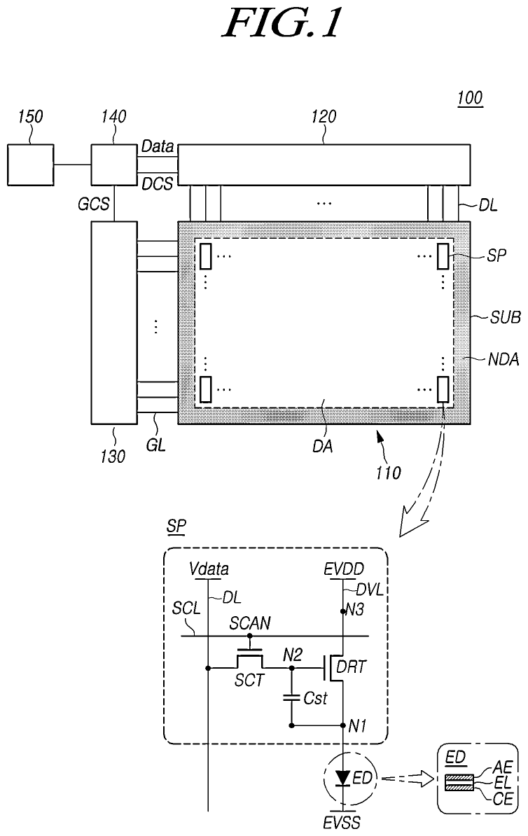

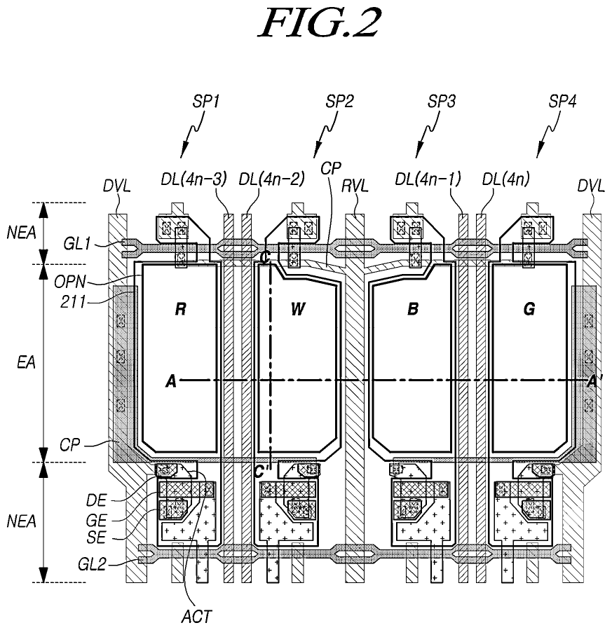

FIG. 1 is a view schematically illustrating a system configuration of a display device according to embodiments of the disclosure. FIG. 2 is a view illustrating a schematic planar structure of a pixel structure disposed on a display panel of a display device according to embodiments of the disclosure.

Referring to FIG. 1, a display driving system of a display device 100 according to embodiments of the disclosure may include a display panel 110 and display driving circuits for driving the display panel 110.

The display panel 110 may include a display area DA in which images are displayed and a non-display area NDA in which no image is displayed. The display panel 110 may include a plurality of subpixels SP disposed on a substrate SUB for image display. The display panel 110 may include a plurality of signal lines disposed on the substrate SUB. For example, the plurality of signal lines may include data lines DL, gate lines GL, driving voltage lines, and the like.

Each of the plurality of data lines DL is disposed to extend in a first direction (e.g., a column direction or a row direction), and each of the plurality of gate lines GL is disposed to extend in a direction crossing the first direction.

The display driving circuits may include a data driving circuit 120, a gate driving circuit 130, and a controller 140 controlling the data driving circuit 120 and the gate driving circuit 130.

The data driving circuit 120 may output data signals (also referred to as data voltages) corresponding to an image signal to the plurality of data lines DL. The gate driving circuit 130 may generate gate signals and output the gate signals to the plurality of gate lines GL. The controller 140 may convert the input image data input from an external host 150 to meet the data signal format used in the data driving circuit 120 and supply the converted image data to the data driving circuit 120.

The data driving circuit 120 may include one or more source driver integrated circuits. For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may be connected to the display panel 110 by a tape automatic bonding (TAB) method, connected to a bonding pad of the display panel 110 by a COG or COP method, connected to the display panel 110 by a COF method, or may be formed in the non-display area NDA of the display panel 110 by a gate in panel (GIP) method.

Referring to FIG. 1, in the display device 100 according to embodiments of the disclosure, each subpixel SP may include a light emitting element ED and a pixel driving circuit for driving the light emitting element ED. The pixel driving circuit may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the second node N2 which is the gate node of the driving transistor DRT. The storage capacitor Cst may be configured to maintain a voltage for a predetermined period of time.

The light emitting element ED may include an anode electrode AE and a cathode electrode CE, and a light emitting layer EL positioned between the anode electrode AE and the cathode electrode CE. The anode electrode AE may be a pixel electrode involved in forming the light emitting element ED of each subpixel SP and may be electrically connected to the first node N1 of the driving transistor DRT. The cathode electrode CE may be a common electrode involved in forming the light emitting elements ED of all the subpixels SP, and a ground voltage EVSS may be applied thereto.

For example, the light emitting element ED may be an organic light emitting diode OLED, an inorganic light emitting diode (LED), or a quantum dot light emitting element, which is a self-luminous semiconductor crystal.

If the display device 100 according to embodiments of the disclosure is an OLED display, each subpixel SP may include an organic light emitting diode (OLED), which by itself emits light, as the light emitting element. If the display device 100 according to embodiments of the disclosure is a quantum dot display, each subpixel SP may include a light emitting element formed of a quantum dot, which is a self-luminous semiconductor crystal. If the display device 100 according to embodiments of the disclosure is a micro LED display, each subpixel SP may include a micro LED, which is self-emissive and formed of an inorganic material, as the light emitting element.

The driving transistor DRT is a transistor for driving the light emitting element ED, and may include a first node N1, a second node N2, and a third node N3. The first node N1 may be a source node or a drain node, and may be electrically connected to the anode electrode AE of the light emitting element ED. The second node N2 is a gate node and may be electrically connected to the source node or drain node of the scan transistor SCT. The third node N3 may be a drain node or a source node, and may be electrically connected to a driving voltage line DVL that supplies the driving voltage EVDD. For convenience of description, in the example described below, the first node N1 may be a source node and the third node N3 may be a drain node.

The scan transistor SCT may switch the connection between the data line DL and the second node N2 of the driving transistor DRT. In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 1 is merely an example for description, and may further include one or more transistors, or one or more storage capacitors. The plurality of subpixels SP may have the same structure, or some of the plurality of subpixels SP may have a different structure. Each of the driving transistor DRT and the scan transistor SCT may be an n-type transistor or a p-type transistor.

The display device 100 according to embodiments of the disclosure may have a top emission structure or a bottom emission structure. The bottom emission structure is described below as an example. For example, in the case of the bottom emission structure, the anode electrode AE may be a transparent conductive film, and the cathode electrode CE may be a reflective metal.

Referring to FIG. 2, a display device 100 according to embodiments includes a plurality of subpixels SP1 to SP4, and each subpixel SP1 to SP4 includes an emission area EA that emits light for displaying and a non-emission area NEA other than the emission area.

The display device 100 according to embodiments includes a bank layer to partition each of the subpixels SP1 to SP4.

The subpixel structure of the display device 100 according to embodiments of the disclosure also includes a “signal line connection structure” that is related to connection of each subpixel to several signal lines, such as the data line DL, gate line GL, driving voltage line DVL, and reference voltage line RVL.

The signal lines may include not only the data line DL for supplying the data voltage Vdata to each subpixel and the gate line GL for supplying the scan signal but also a reference voltage line RVL for supplying the reference voltage to each subpixel and a driving voltage line DVL for supplying the driving voltage EVDD.

In the disclosure and drawings, the subpixel connected to the 4n−3th data line DL(4n−3), the subpixel connected to the 4n−2th data line DL(4n−2), the subpixel connected to the 4n−1th data line DL(4n−1), and the subpixel connected to the 4nth data line DL(4n) may be, e.g., a red (R) subpixel, a white (W) subpixel, a blue (W) subpixel, and a green (G) subpixel, respectively.

However, without limitations thereto, the red (R) subpixel, the white (W) subpixel, the blue (B) subpixel, and the green (G) subpixel may be arranged in other various orders. A pixel structure having the order of the red (R) subpixel SP1, the white (W) subpixel SP2, the blue (B) subpixel SP3, and the green (G) subpixel SP4 is described below.

As described above, when the basic unit of the signal line connection structure includes four subpixels SP1 to SP4 connected to four data lines DL(4n−3), DL(4n−2), DL(4n−1), and DL(4n), one reference voltage line RVL for supplying the reference voltage and two driving voltage lines DVL for supplying the driving voltage EVDD may be formed for the four subpixels SP1 to SP4. The four data lines DL(4n−3), DL(4n−2), DL(4n−1), and DL(4n) are connected to the four subpixels SP1 to SP4, respectively. Further, one gate line GL(m) (where 1≤m≤M) is connected to the four subpixels SP1 to SP4.

In the display device 100 according to embodiments of the disclosure, the organic light emitting element emitting white (W) light is commonly disposed in each subpixel, and a red (R) color filter, a blue (B) color filter, and a green (G) color filter are disposed in the red (R) subpixel SP1, the blue (B) subpixel SP3, and the green (G) subpixel SP4, respectively. No separate color filter is disposed in the white (W) subpixel SP2.

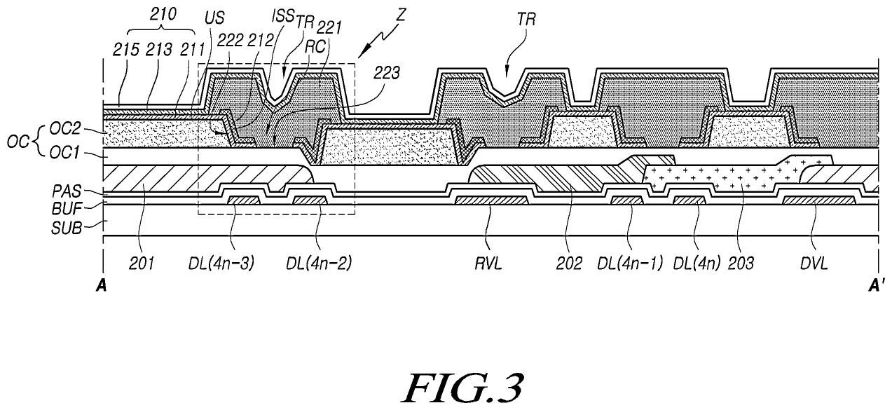

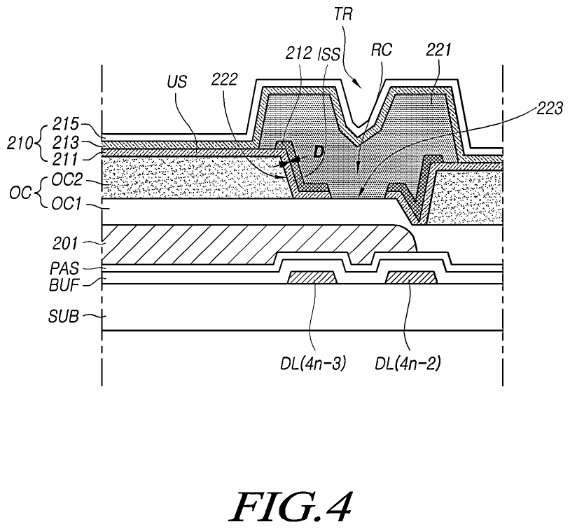

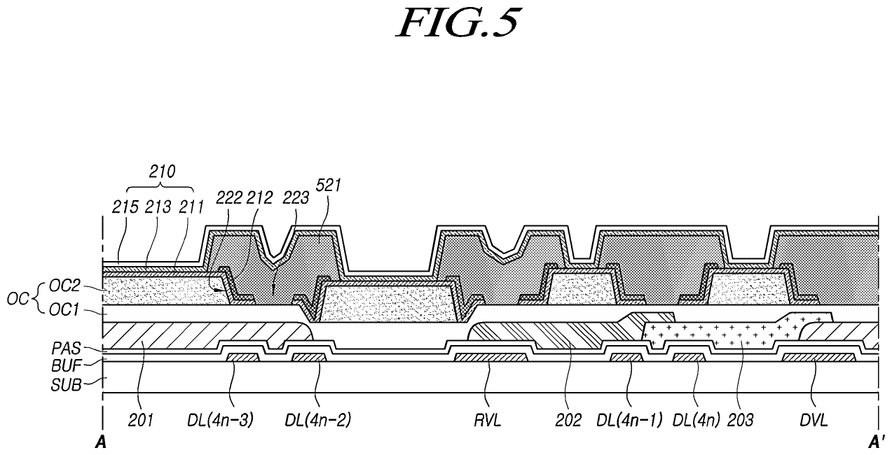

FIG. 3 is a cross-sectional view illustrating an example structure, taken along line A-A′ of FIG. 2. FIG. 4 is an enlarged view illustrating a cross-sectional structure of portion Z of FIG. 3. FIG. 5 is a cross-sectional view illustrating another example structure, taken along line A-A′ of FIG. 2. What is identical or similar to those described in connection with FIGS. 1 to 2 may be omitted or briefly described below.

Referring to FIGS. 3 and 5, a display device according to embodiments of the disclosure includes a substrate SUB including a plurality of subpixels SP1 to SP4, an overcoat layer OC disposed on the substrate SUB and including a recess RC positioned between the subpixels SP1 to SP4, a first electrode 211 disposed to cover an upper surface US of the overcoat layer OC and an inclined surface 222 of the recess RC and including a transparent conductive material, a reflection layer 212 disposed on the first electrode 211 on the inclined surface 222 of the recess RC and including a metal or a metal alloy, and a bank layer 221 positioned in the recess RC and disposed on the reflection layer 212. The inclined surface 222 of the recess RC and an inclined side surface ISS of the second overcoat layer OC2 indicate the same surface. The inclined side surface ISS of the second overcoat layer OC2 extends from the upper surface US of the second overcoat layer OC2.

A plurality of subpixels SP1 to SP4 may be arranged on the substrate SUB. The substrate SUB may be selected as a material for forming an element having an improved mechanical strength or dimensional stability.

The substrate SUB may be not only a glass substrate, but also a plastic substrate including polyethylene terephthalate (PET), polyethylene naphthalate (PEN), polyimide, or the like.

A plurality of signal lines DLs, RVL, and DVL may be disposed on the substrate SUB, and a buffer layer BUF may be disposed on the plurality of signal lines DLs, RVL, and DVL.

The buffer layer BUF serves to protect a thin film transistor (not shown) formed in a subsequent process from impurities such as alkali ions flowing out of the substrate SUB. Further, the buffer layer BUF serves as an insulation film. The buffer layer BUF may be a single layer of silicon oxide (SiOₓ) or silicon nitride (SiNₓ) or multiple layers thereof.

The passivation layer PAS may be disposed on the buffer layer BUF.

The passivation layer PAS is an insulation film for protecting elements thereunder, and may be a single layer of silicon oxide (SiOₓ) or silicon nitride (SiNₓ) or multiple layers thereof. Also, the passivation layer PAS may be omitted.

A color filter may be disposed on the passivation layer PAS. The color filter may be disposed to correspond to each subpixel SP1 to SP4.

A red (R) color filter 201 may be disposed in the red (R) subpixel SP1, and a blue (B) color filter 202 and a green (G) color filter 203 may be disposed in the blue (B) subpixel SP3 and the green (G) subpixel SP4, respectively.

A separate color filter may not be disposed in the white (W) subpixel SP2, and an overcoat layer OC may be disposed. Since the overcoat layer OC, the passivation layer PAS, and the buffer layer BUF stacked in the white (W) subpixel SP2 are formed of a transparent material, a separate color filter may not be disposed.

The overcoat layer OC may be disposed on the color filter and the passivation layer PAS.

The overcoat layer OC may have an area where a partial step is formed due to patterns formed below. Further, the overcoat layer OC may provide a flat surface for mitigating a height step of the structure thereunder.

In the display device according to embodiments of the disclosure, a recess RC may be formed by utilizing a height step formed in the overcoat layer OC.

The overcoat layer OC may be disposed on the color filter and the passivation layer PAS without being disconnected. In this case, the overcoat layer OC may have a step between an area where the color filter is disposed and an area where the color filter is not disposed.

For example, the overcoat layer OC may be formed by forming an entire surface on the color filter and the passivation layer PAS and then etching a boundary area between each of the subpixels SP1 to SP4.

The overcoat layer OC may include a first overcoat layer OC1 and a second overcoat layer OC2 disposed on the first overcoat layer OC1.

The first overcoat layer OC1 may be disposed on the color filter and the passivation layer PAS without being disconnected. In this case, the first overcoat layer OC1 may have a step between the area where the color filter is disposed and the area where the color filter is not disposed.

The second overcoat layer OC2 may be disposed on the first overcoat layer OC1, and may be disposed to correspond to the opening OPN of each of the subpixels SP1 to SP4 partitioned by the bank layer 221.

For example, the second overcoat layer OC2 may be formed by forming an entire surface on the first overcoat layer OC1 and then etching a boundary area between each of the subpixels SP1 to SP4.

Further, the second overcoat layer OC2 may be formed on the first overcoat layer OC1 in an area corresponding to an opening of each of the subpixels SP1 to SP4.

For example, the second overcoat layer OC2 may be formed on the first overcoat layer OC1 by using a mask corresponding to an opening and a boundary area of each of the subpixels SP1 to SP4.

The overcoat layers OC, OC1, and OC2 may be formed of an organic film such as an acryl resin, an epoxy resin, a phenolic resin, a polyamide resin, a polyimide resin, or the like.

The overcoat layer OC may include a recess RC. The recess RC may be positioned and disposed between each of the subpixels SP1 to SP4.

For example, the recess RC may be formed by etching an area where the recess RC is to be disposed after forming the overcoat layer OC, or an area where the overcoat layer OC is not formed by forming the overcoat layer OC in the area corresponding to the opening of each subpixel SP1 to SP4 may be the recess RC.

The recess RC may include an inclined surface 222 and a lower surface 223.

In the recess RC, a width of an upper side of the recess RC may be larger than a width of a lower side of the recess RC. In other words, the width of the recess RC may increase as it moves farther away from the substrate.

The inclined surface 222 of the recess RC may correspond to the side surface of the area where the overcoat layer OC is etched or the side surface of the area where the overcoat layer OC is not formed. That is, for example, in FIG. 4, the inclined surface 222 of the recess RC corresponds to the surface between the second overcoat layer OC2 and the first electrode 211.

The lower surface 223 of the recess RC may correspond to the lower surface of the area where the overcoat layer OC is etched or the lower surface of the area where the overcoat layer OC is not formed. To be specific, the lower surface 223 of the recess RC may correspond to a top surface of the first overcoat layer OC1. Here, the second overcoat layer OC2 is etched or the second overcoat layer OC2 is not formed at a location where the recess RC is located.

The recess RC may be disposed between the second overcoat layers OC2 positioned in the areas corresponding to each of the subpixels SP1 to SP4, on the first overcoat layer OC1.

For example, after the first overcoat layer OC1 is formed on the front surface of the substrate, the second overcoat layer OC2 may be formed at the position corresponding to the opening of each of the subpixels SP1 to SP4, thereby forming the recess RC between each of the subpixels SP1 to SP4.

The inclined surface 222 of the recess RC may correspond to the side surface of the second overcoat layer OC2, and the lower surface 223 of the recess RC may correspond to a portion of the upper surface of the first overcoat layer OC1.

The organic light emitting element 210 may be disposed on the overcoat layer OC.

The organic light emitting element 210 may include a first electrode 211, an organic light emitting layer 213, and a second electrode 215.

An encapsulation layer (not shown) in which a plurality of organic films and inorganic films are stacked may be further formed on the organic light emitting element 210.

The first electrode 211 is a pixel electrode serving as an anode, and may be independently disposed in each of the subpixels SP1 to SP4.

The first electrode 211 may be disposed to cover the upper surface of the overcoat layer OC and the inclined surface 222 of the recess RC. Further, the first electrode 211 may be disposed to cover the upper surface of the second overcoat layer OC2 and the inclined surface 222 of the recess RC.

The first electrode 211 may be disposed to be disconnected on the lower surface 223 of the recess RC.

The first electrode 211 may be formed of a metal, a metal alloy, or a combination of a metal and an oxide metal, and may include a transparent conductive material. For example, the first electrode 211 may include at least one of indium tin oxide (ITO), indium zinc oxide (IZO), or indium tin zinc oxide (ITZO).

A reflection layer 212 may be disposed on the first electrode 211.

The reflection layer 212 may be disposed on the first electrode 211 on the inclined surface 222 of the recess RC and may include a metal or a metal alloy.

A display device according to embodiments of the disclosure may include a multi-layer structure including a first electrode 211 and a reflection layer 212 disposed on the first electrode 211. For example, the first electrode 211 may be disposed in the area of the opening OPN in which light emitted from the organic light emitting layer 213 is directly extracted to the outside, and the multi-layer structure of the first electrode 211 and the reflection layer 212 may be formed in the area of the bank layer 221.

By including the multi-layer structure in which the first electrode 211 of the transparent conductive material is disposed in the area of the opening OPN and the first electrode 211 and the reflection layer 212 on the first electrode 211 are disposed in the area of the bank layer 221, the distance between the organic light emitting layer 213 and the side reflection layer 212 may be reduced, thereby enhancing light extraction efficiency.

As shown in FIG. 3, the bank layer 221 also includes a trench TR. A top surface of the bank layer 221 protrudes downward toward the substrate SUB to form the trench TR. In one embodiment, the trench TR does not overlap with the reflection layer 212. The organic light emitting layer 213 extends from the organic light emitting element 210 and extends over the bank layer 221. The organic light emitting layer 213 also extends into the trench TR of the bank layer 221. Similarly, the second electrode 215 extends from the organic light emitting element 210 and extends over the bank layer 221. The second electrode 215 also extends into the trench TR of the bank layer 221.

FIG. 4 is an enlarged cross-sectional view illustrating a portion Z illustrated in FIG. 3 to which a structure according to embodiments of the disclosure is applied.

In the conventional structure, on the side surface of the organic light emitting element are stacked the first electrode, which is a transparent electrode, the bank layer, the organic light emitting layer, and the second electrode, which is the reflective electrode, in the order thereof. According to the conventional structure, light emitted from the organic light emitting layer and directed to the side surface may pass through a structure such as the bank layer, may be reflected from the second electrode, and may be extracted to the outside. However, due to the travelling distance of the light directed to the side surface, the light is lost or is not reflected to the outside, and thus the light extraction efficiency is reduced.

In contrast, referring to FIG. 4, in the structure of the display device according to embodiments of the disclosure, the first electrode 211, which is a transparent electrode, and the reflection layer 212 are stacked, in the order thereof, on the side surface of the organic light emitting element 210. In other words, the distance D between the first electrode 211 and the reflection layer 212 on the side surface of the organic light emitting element 210 where the bank layer 221 is disposed may be defined as 0. Further, it can also be said that the first electrode 211 and the reflection layer 212 at the inclined side surface of the second overcoat layer OC2 are in direct contact with each other such that the distance D is defined as 0.

Accordingly, in the display device according to embodiments of the disclosure, the travelling distance of the light emitted from the organic light emitting layer 213 of the organic light emitting element 210 may be reduced by reducing the distance between the organic light emitting layer 213 and the side reflection layer 212 as compared to the conventional structure, thereby enhancing light extraction efficiency.

The reflection layer 212 may include a metal or a metal alloy. For example, the reflection layer 212 may include any one selected from the group consisting of silver (Ag), aluminum (Al), magnesium (Mg), chromium (Cr), titanium (Ti), nickel (Ni), tungsten (W), gold (Au), tantalum (Ta), copper (Cu), cobalt (Co), iron (Fe), molybdenum (Mo), platinum (Pt), and an alloy thereof.

The reflection layer 212 may include a first portion FPO disposed to extend over a portion of the upper surface US of the overcoat layer OC, and may include a second portion SPO disposed on the inclined surface 222 of the recess RC.

Further, the reflection layer 212 may be disposed to extend over a portion of the upper surface of the second overcoat layer OC2 adjacent to the inclined surface of the recess RC.

In this case, the width of the first portion FPO of the reflection layer 212 projected onto the plane may be larger than the width of the second portion SPO of the reflection layer 212 projected onto the plane.

The reflection layer 212 may be disposed in an area overlapping the first electrode 211 in the recess RC. For example, when the first electrode 211 is disposed to be disconnected on the lower surface 223 of the recess RC, the reflection layer 212 may also be disposed to be disconnected to overlap the first electrode 211.

The reflection layer 212 may be disposed to be covered by the bank layer 221.

The first portion FPO of the reflection layer 212 may be disposed to be entirely covered by the bank layer 221.

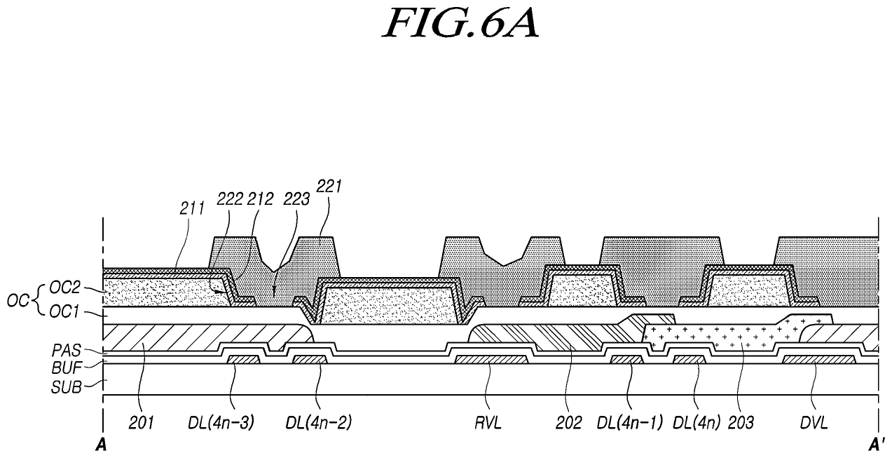

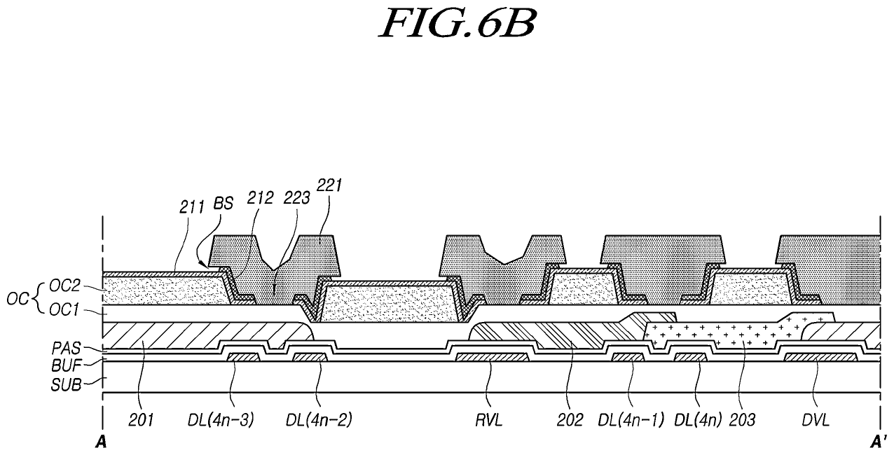

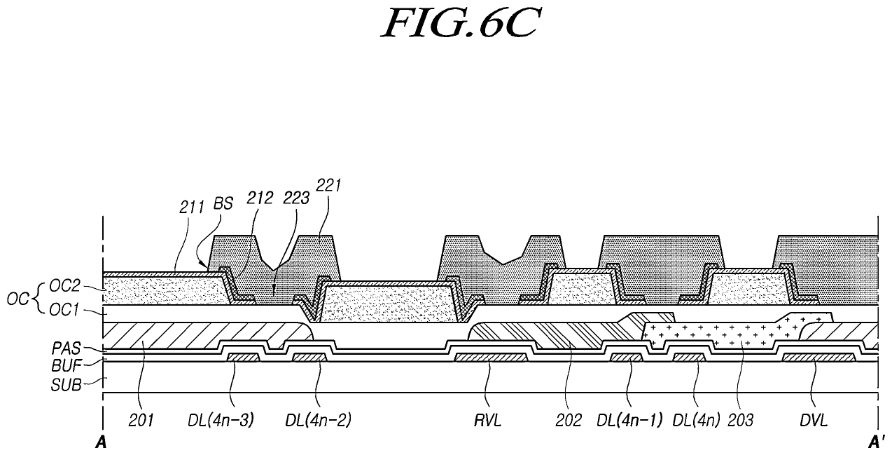

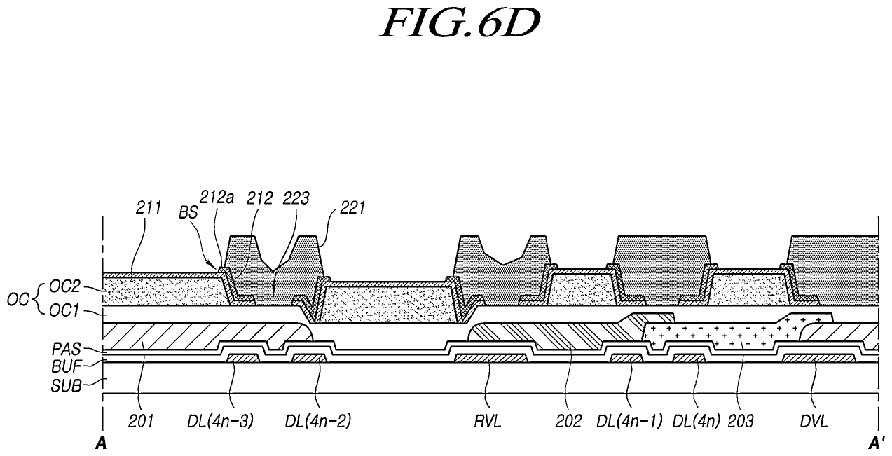

Further, the first portion FPO of the reflection layer 212 may include a protrusion 212a (see FIG. 6D) protruding to the outside of the bank layer 221. In other words, a portion of the first portion FPO of the reflection layer 212 may be covered by the bank layer 221, and the protrusion 212a, which is an end of the first portion FPO, may be exposed to the outside of the bank layer 221. The entire first portion FPO of the reflection layer 212 may be a protrusion 212a exposed to the outside of the bank layer 221.

The protrusion 212a may be an oxide insulation layer that is an oxide of the metal or metal alloy.

In other words, the protrusion 212a may be an oxide of a metal or a metal alloy forming the reflection layer 212. For example, the protrusion 212a may be an oxide insulation layer that is formed of an oxide of any one selected from the group consisting of silver (Ag), aluminum (Al), magnesium (Mg), chromium (Cr), titanium (Ti), nickel (Ni), tungsten (W), gold (Au), tantalum (Ta), copper (Cu), cobalt (Co), iron (Fe), molybdenum (Mo) platinum (Pt), and an alloy thereof.

Even if the protrusion 212a includes an oxide insulation layer and the protrusion 212a comes into contact with the first electrode 211, a current does not flow between the protrusion 212a and the first electrode 211 due to a work function difference, and thus the corresponding area may remain a non-emission area.

The bank layer 221 may be disposed on the overcoat layer OC, the first electrode 211, and the reflection layer 212.

The bank layer 221 may be disposed such that a first portion FPO of the reflection layer 212 is covered.

The bank layer 221 may be positioned in the recess RC and may define an opening OPN of each of the subpixels SP1 to SP4.

The upper surface of the bank layer 221 may be a flat surface or may have a concave shape or a convex shape. For example, the upper surface of the bank layer 221 may have a concave shape.

Referring to FIGS. 2 and 3, the bank layer 221 adjacent to the white (W) subpixel SP2 may have a concave upper surface.

The red (R) subpixel SP1, the blue (B) subpixel SP3, and the green (G) subpixel SP4 may have the color filters 201, 202, and 203, respectively, disposed under their openings OPN, and the white (W) subpixel SP2 may have no color filter disposed. The color filters 201, 202, and 203 may be disposed to extend to under the adjacent bank layers 221, color filters may be disposed to overlap under some bank layers 221, and one color filter may be disposed under some bank layers 221.

As one color filter is disposed under the bank layer 221 adjacent to the white (W) subpixel SP2, a step occurs in the central portion of the bank layer 221, so that the upper surface of the bank layer may have a concave shape.

The bank layer may be a transparent bank layer 221 or a black bank layer 521. For instance, in FIG. 3, the bank layer is a transparent bank layer 221. In FIG. 5, on the other hand, the bank layer is a black bank layer 521.

Referring to FIG. 5, the display device according to embodiments of the disclosure may include a black bank layer 521 as the bank layer.

The transparent bank layer 221 may include a single layer or multiple layers of silicon nitride (SiNₓ), silicon oxide (SiOₓ), silicon oxynitride (SiOₓN_{y}), aluminum oxide (AlOₓ), and aluminum oxynitride (AlOₓN_{y}).

For example, the transparent bank layer 221 may include silicon dioxide (silica or silicon dioxide (SiO₂)).

The black bank layer 521 may include a colored material to reduce or minimize reflection by external light, thereby increasing optical density (OD) indicating the degree of light blocking. When the optical density increases, reflection by external light may be reduced or minimized, and thus a polarizing plate may be excluded.

The black bank layer 521 may include at least one selected from among carbon black, black pigment, black dye, black resin, graphite powder, gravure ink, black spray, black enamel, or the like.

The organic light emitting layer 213 and the second electrode 215 may be disposed on the first electrode 211 and the bank layer 221.

The organic light emitting layer 213 may include multiple layers of a hole injection layer, a hole transport layer, a light emitting material layer, an electron transport layer, and an electron injection layer to increase light emission efficiency.

The second electrode 215 is a common electrode serving as a cathode, and may be commonly disposed in all subpixels SP1 to SP4.

The second electrode 215 may be a transflective electrode or a reflective electrode.

For example, the second electrode 215 may be any one selected from the group consisting of silver (Ag), aluminum (Al), magnesium (Mg), chromium (Cr), titanium (Ti), nickel (Ni), tungsten (W), gold (Au), tantalum (Ta), copper (Cu), cobalt (Co), iron (Fe), molybdenum (Mo), and platinum (Pt), or an alloy of the metals.

The display device according to embodiments of the disclosure may enhance light extraction efficiency by reducing the distance between the organic light emitting layer 213 and the side reflection layer 212 by applying a multi-layer structure of the first electrode 211 and the reflection layer 212 on the first electrode 211 in the area of the bank layer 221 and disposing the first electrode 211 formed of a transparent conductive material in the area of the opening OPN.

FIGS. 6A, 6B, 6C, and 6D are views illustrating a process of forming a display panel according to embodiments of the disclosure. What is identical or similar to those described in connection with FIGS. 1 to 5 may be omitted or briefly described below.

Referring to FIG. 6A, a second overcoat layer OC2 is disposed on the first overcoat layer OC1 to form a recess RC.

A transparent electrode material and a metal material are deposited on the front surfaces of the first overcoat layer OC1 and the second overcoat layer OC2 to form the first electrode 211 and the reflection layer 212 on the first electrode 211.

The first electrode 211 and the reflection layer 212 may be simultaneously etched in the recess RC to pattern the first electrode 211 and the reflection layer 212 to be disconnected on the lower surface 223 of the recess RC.

The bank layer 221 defining the opening OPN is deposited on the first electrode 211, the reflection layer 212, and the first overcoat layer OC1 to form the bank layer 221.

The bank layer 221 may be formed by coating, exposing, developing, and curing a bank material.

Referring to FIG. 6B, a metal material used as the reflection layer 212 is etched in the opening OPN area using the bank layer 221 as a mask so that the first electrode 211 remains in the opening OPN area. At this time, the metal material may be removed using wet or dry etching.

When the metal material used as the reflection layer 212 is etched in the opening OPN area, an undercut may be formed in the lower side area BS of the bank layer 221.

If the reflection layer 212 is patterned using the bank layer 221 as a mask, it is possible to mitigate a reduction in aperture ratio due to the alignment tolerance.

FIGS. 6C and 6D are views illustrating a process of removing an undercut formed in the lower side area BS of the bank layer 221 as a separate process.

Referring to FIG. 6C, the step of reflowing the bank layer 221 may be included. As the bank layer 221 is reflowed through the curing process, the bank material is formed to cover the undercut formed in the lower side area BS of the bank layer 221. Accordingly, the undercut of the bank layer 221 may be removed.

Thereafter, the organic light emitting layer 213 and the second electrode 215 are sequentially stacked to manufacture the display device illustrated in FIG. 3.

Referring to FIG. 6D, another process of removing the undercut formed in the lower side area BS of the bank layer 221 may include the step of ashing the bank layer 221. The undercut of the bank layer 221 may be removed by removing the bank material above the undercut through the ashing process.

Further, the protrusion 212a, which is a protruding portion of the reflection layer 212, may form an oxide insulation layer by treatment with the oxygen (O 2) used in the ashing process. Therefore, even when the protrusion 212a contacts the first electrode 211, a current does not flow between the protrusion 212a and the first electrode 211 due to a work function difference, and thus the corresponding area may remain a non-emission area.

Thereafter, the organic light emitting layer 213 and the second electrode 215 are sequentially stacked to manufacture the display device illustrated in FIG. 3.

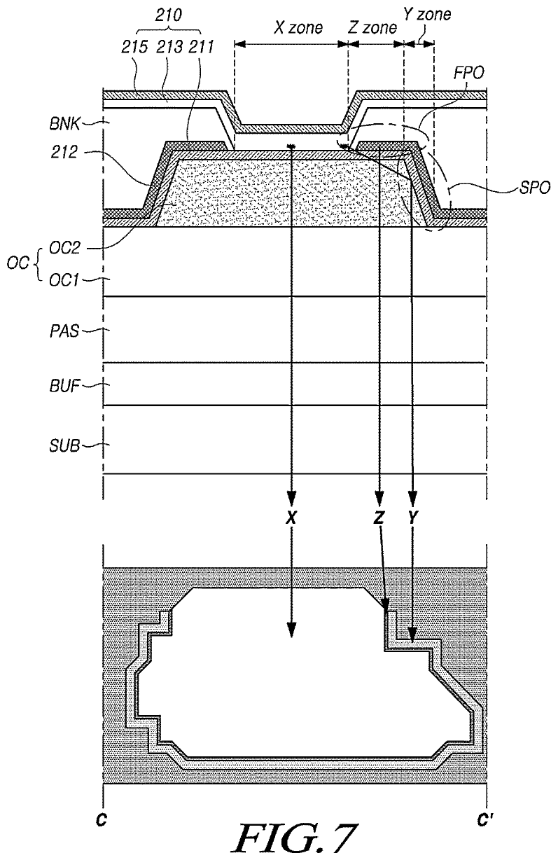

FIG. 7 is a view illustrating an emission area and a non-emission area of a subpixel in a display device according to embodiments of the disclosure. For example, FIG. 7 is a view illustrating a cross-sectional structure of the white (W) subpixel SP2 illustrated in FIGS. 2, 3, and 5, and an emission width of each area projected on a plane when the white (W) subpixel SP2 emits light. In the following description, those identical or similar to what has been described in connection with FIGS. 1 to 6D are briefly described.

Referring to FIG. 7, the subpixel may include an X zone which is an emission area of the subpixel, and a Y zone and a Z zone which are non-emission areas of the subpixel.

The X zone is an opening area where the organic light emitting element 210 including the first electrode 211, the organic light emitting layer 213, and the second electrode 215 is disposed. In the X zone, light emitted from the organic light emitting layer 213 may be directly extracted to the outside.

The Y zone is an area where the reflection layer 212 has a second portion SPO disposed on the inclined surface of the recess RC, and includes a first electrode 211 including a transparent conductive material and a reflection layer 212. Since the Y zone includes the reflection layer 212, light traveling sideways from the organic light emitting layer 213 disposed in the emission area of the subpixel may be reflected from the second portion SPO of the reflection layer 212 and extracted to the outside.

The Z zone is an area where the reflection layer 212 has a first portion FPO disposed to extend over a portion of the upper surface of the overcoat layer OC, and includes a first electrode 211, a reflection layer 212, a bank layer BNK, an organic light emitting layer 213, and a second electrode 215. In the Z zone, since the bank layer BNK is disposed between the first electrode 211 and the reflection layer 212 and the organic light emitting layer 213, light may not be generated in the organic light emitting layer 213, and since the organic light emitting layer 213 disposed in the emission area of the subpixel and the first portion FPO of the reflection layer 212 are disposed parallel to each other, it may be difficult for light traveling sideways to be reflected from the reflection layer 212 and extracted to the outside.

Referring to FIG. 7, in the subpixel, the width of the first portion FPO included in the Z zone projected onto the plane is larger than the width of the second portion SPO included in the Y zone projected onto the plane. In other words, the width of each area projected onto the plane in the subpixel has a relationship of X zone>Z zone>Y zone.

On the other hand, when the subpixel emits light, the emission width of each area projected on the plane has a relationship of X zone>Y zone>Z zone. As the light emitted from the organic light emitting layer 213 is directly extracted to the outside, the light is partially emitted not only in the Y zone but also in the Z zone, and as the light traveling sideways from the organic light emitting layer 213 disposed in the emission area of the subpixel is reflected from the second portion SPO of the reflection layer 212 and extracted to the outside, the light is partially emitted not only in the Y zone but also in the Z zone, resulting in the Z zone having the narrowest emission width.

Meanwhile, FIG. 7 illustrates the cross-sectional structure and the emission width of the white (W) subpixel SP2 in which no separate color filter is disposed, but the same may be applied to the red (R), blue (B), and green (G) subpixels SP1, SP3, and SP4 in which the color filters 201, 202, and 203 are disposed.

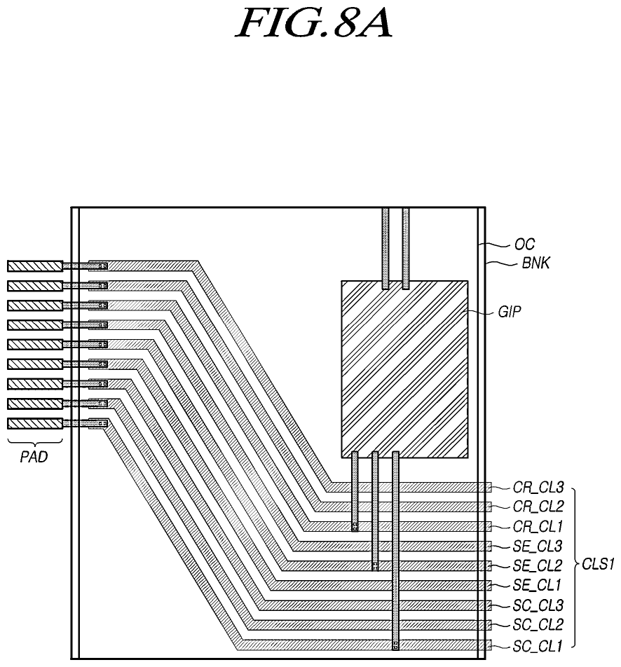

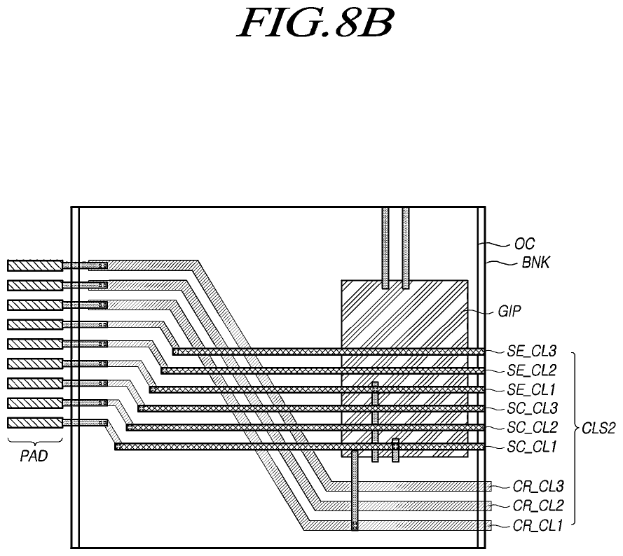

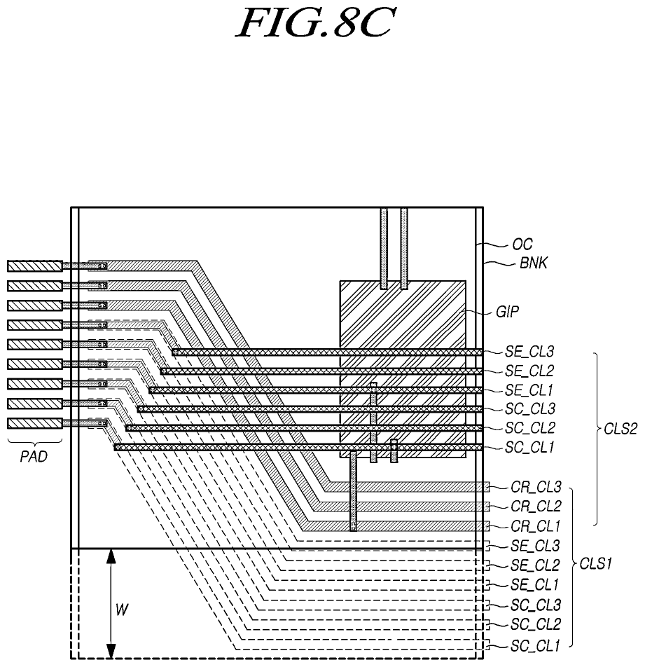

FIG. 8A is a view illustrating a schematic planar structure of a bezel area to which a structure according to embodiments of the disclosure is not applied. FIG. 8B is a view illustrating a schematic planar structure of a bezel area to which a structure according to embodiments of the disclosure is applied. FIG. 8C is a view illustrating a schematic planar structure of a bezel area for comparing the bezel area shown in FIG. 8A with the bezel area shown in FIG. 8B. What is identical or similar to those described in connection with FIGS. 1 to 7 may be omitted or briefly described below.

Referring to FIG. 8A, the clock line portion CLS1 of the bezel area requires many various types of clock lines SC_CL1 to 3, SE_CL1 to 3, and CR_CL1 to 3 for supplying many clock signals having different phases to the gate driving unit GIP for gate driving between the pad PAD and the gate driving unit GIP.

For example, six-phase clock signals may be used, but in the display device according to embodiments of the disclosure, only three-phase clock signals are shown for convenience purposes.

A three-phase sense clock signal required for generating the sense signal SENSE, a three-phase scan clock signal required for generating the scan signal SCAN, and a three-phase carry clock signal for controlling to set and reset between stages in the gate driving unit GIP may be required. In other words, sequential driving requires 9-phase clock signals.

For convenience, in the display device in which three phases are shown, according to sequential driving, because a considerable number of clock lines SC_CL1 to 3, SE_CL1 to 3, and CR_CL1 to 3 are disposed on the same layer of the bezel area, the area where the clock line portion CLS1 are formed in the bezel area is inevitably increased. Accordingly, the bezel of the display device may be enlarged.

Referring to FIG. 8B, in the display device according to an embodiment of the disclosure, some clock lines SC_CL1 to 3 and SE_CL1 to 3 are disposed on the remaining clock lines CR_CL1 to 3 in the clock line portion CLS2 of the bezel area to connect the pad PAD and the gate driving unit GIP.

Referring to FIG. 8B, the clock line portion CLS2 includes first clock lines CR_CL1 to 3 disposed on the substrate, and includes second clock lines SC_CL1 to 3 and SE_CL1 to 3 disposed on the gate driving unit GIP. In other words, the first clock lines CR_CL1 to 3 and the second clock lines SC_CL1 to 3 and SE_CL1 to 3 are disposed on different layers. Further, the second clock lines SC_CL1 to 3 and SE_CL1 to 3 may be formed of multi-layer lines including a first electrode and a reflection layer disposed on the first electrode.

Accordingly, in the clock line portion CLS2 of the bezel area, some clock lines SC_CL1 to 3, SE_CL1 to 3 may be disposed on the gate driving unit GIP such that the clock lines SC_CL1 to 3, SE_CL1 to 3, and CR_CL1 to 3 are disposed on different layers, thereby reducing the area where the clock line portion CLS2 are formed in the bezel area. Accordingly, the bezel of the display device may be reduced.

Referring to FIG. 8C, it may be identified that the bezel area including the clock line portion CLS2 to which the structure according to embodiments of the disclosure is applied has a width reduced by W as compared to the bezel area including the clock line portion CLS1 to which the structure according to embodiments of the disclosure is not applied.

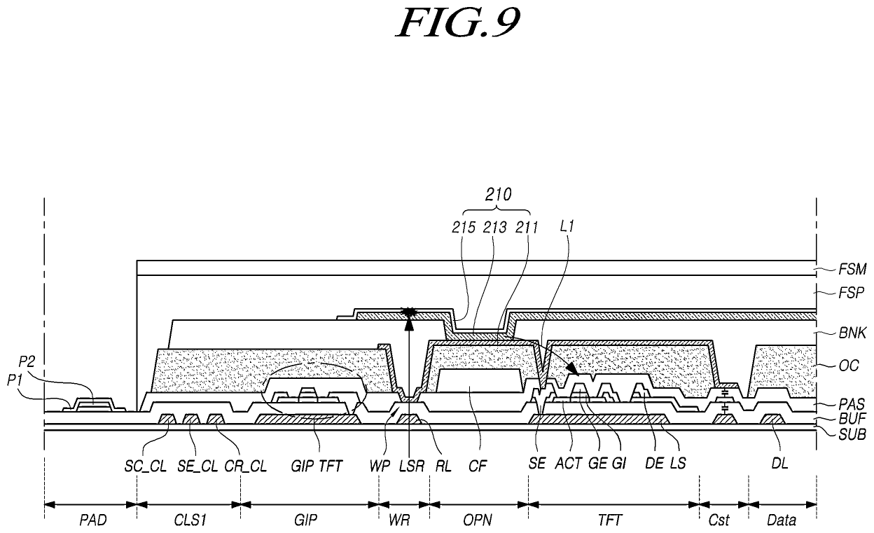

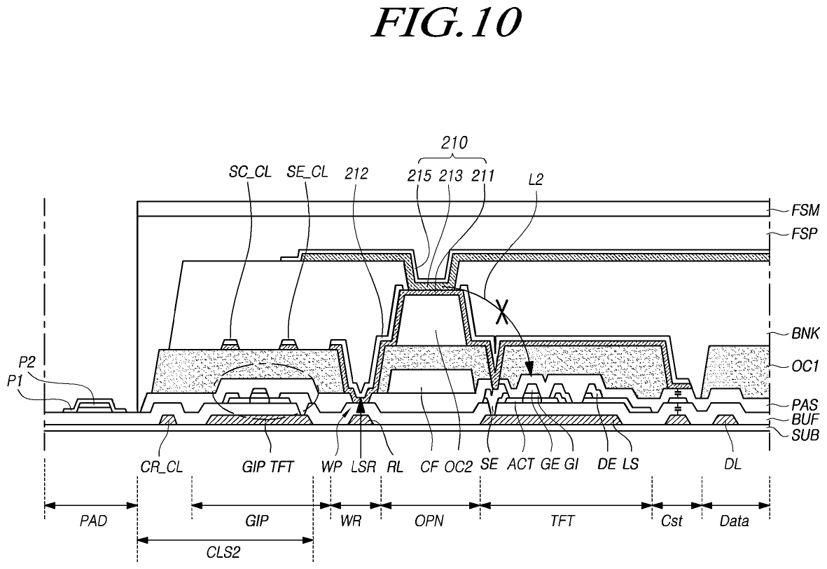

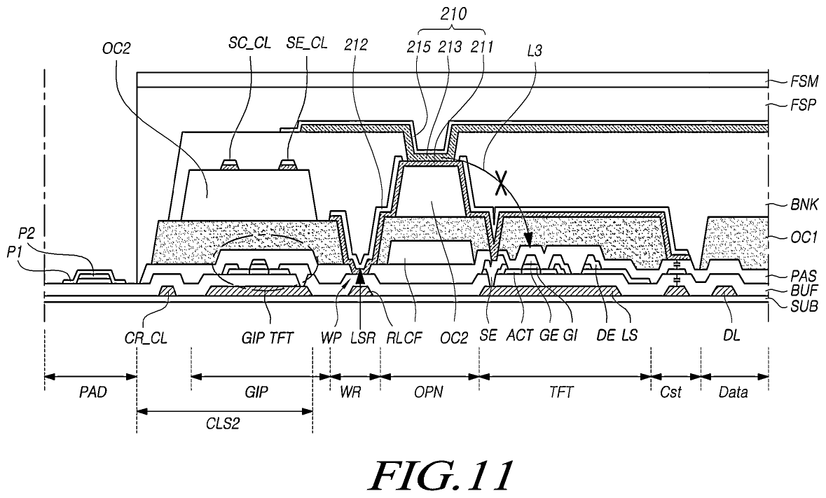

FIG. 9 is a view illustrating a schematic cross-sectional structure of a display panel to which a structure according to embodiments of the disclosure is not applied. FIG. 10 is a view illustrating a schematic cross-sectional structure of a display panel to which a structure according to embodiments of the disclosure is applied. FIG. 11 is a view illustrating a schematic cross-sectional structure of a display panel to which a structure according to other embodiments of the disclosure is applied. What is identical or similar to those described in connection with FIGS. 1 to 8C may be omitted or briefly described below.

Referring to FIG. 9, the light L1 emitted from the organic light emitting layer 213 of the organic light emitting element 210 may pass through the first electrode 211, which is a transparent electrode, and may travel to the circuit unit in which the thin film transistor TFT is disposed. The light L1 traveling to the circuit unit may accelerate deterioration of the active layer ACT of the thin film transistor TFT.

Referring to FIG. 9, when the subpixel is a dark spot, a welding repair portion WR connecting the repair line RL and the first electrode 211 of the subpixel by using a laser beam LSR may be provided at the welding point WP of the rear surface to share the signal of the adjacent subpixel. However, when the laser beam LSR having a wavelength of 532 nm or 1064 nm is radiated to the first electrode during repair, the laser beam LSR may be transmitted through the first electrode, which is a transparent electrode, damaging the second electrode, which is the cathode electrode. When the second electrode, which is the cathode electrode, is damaged, the progressive dark spot defect rate may increase due to insufficient encapsulation capability of the organic light emitting element.

Referring to FIG. 9, since a considerable number of clock lines SC_CL, SE_CL, and CR_CL are disposed on the same layer in the clock line portion CLS1, the area where the clock line portion CLS1 are formed in the bezel area may be increased, and thus the bezel of the display device may be increased.

Referring to FIGS. 10 and 11, the display device according to embodiments of the disclosure may include a plurality of subpixels SP1 to SP4 including an emission area and a non-emission area and a substrate SUB on which the bank layer BNK defining the opening OPN of each of the plurality of subpixels is disposed.

The emission area may include a first overcoat layer OC1 disposed on the substrate SUB, a second overcoat layer OC2 positioned in an area corresponding to the opening OPN and disposed on the first overcoat layer OC1, and an organic light emitting element 210 disposed on the second overcoat layer OC2.

In the emission area, the organic light emitting element 210 may include a first electrode 211, an organic light emitting layer 213, and a second electrode 215, which are disposed on the second overcoat layer OC2.

In the emission area, a reflection layer 212 may be disposed on the first electrode 211, and the reflection layer 212 may be disposed to be spaced apart from the organic light emitting layer 213. A bank layer BNK may be disposed in a space in which the reflection layer 212 and the organic light emitting layer 213 are spaced apart from each other while covering the reflection layer 212.

The non-emission area may include a thin film transistor TFT disposed on the substrate SUB, a first overcoat layer OC1 disposed on the thin film transistor TFT, a first electrode 211 disposed on the first overcoat layer OC1, and a reflection layer 212 disposed on the first electrode 211.

In the non-emission area, the bank layer BNK may be disposed on the reflection layer 212 and the first overcoat layer OC1.

In the non-emission area, the organic light emitting layer 213 and the second electrode 215 disposed in the emission area may be disposed to extend on the bank layer BNK.

In the emission area and the non-emission area, the encapsulation layer FSP and the encapsulation substrate FSM may be disposed on the bank layer BNK and the second electrode 215.

Meanwhile, the plurality of subpixels SP1 to SP4 disposed in the display device according to embodiments of the disclosure may include the emission area and non-emission area of the subpixel illustrated in FIG. 7. In other words, the plurality of subpixels SP1 to SP4 may include the X zone which is the emission area of the subpixel, and the Y zone and the Z zone which are non-emission areas of the subpixel. The emission area and non-emission area of the subpixels are identical or similar to those described with reference to FIG. 7, and are thus omitted or briefly described.

Referring to FIGS. 10 and 11, the light L2 and L3 emitted from the organic light emitting layer 213 of the organic light emitting element 210 may not pass through the reflection layer 212 disposed on the first electrode 211, which is a transparent electrode, and thus may not proceed to the circuit unit where the thin film transistor TFT is disposed. The reflection layer 212 may protect the active layer ACT of the thin film transistor TFT from the light L2 and L3 emitted from the organic light emitting layer 213. In other words, the reflection layer 212 may serve as a light blocking layer for blocking the light L2 and L3 emitted from the organic light emitting layer 213.

Referring to FIGS. 10 and 11, the non-emission area may include a clock line portion CLS2 and a gate driving unit GIP.

The clock line portion CLS2 may include first clock lines CR_CL and second clock lines SC_CL and SE_CL disposed on different layers. For example, the clock line portion CLS2 may include first clock lines CR_CL disposed on the substrate SUB and second clock lines SC_CL and SE_CL disposed on the gate driving unit GIP.

The gate driving unit GIP may include a gate thin film transistor GIP TFT disposed on the substrate SUB, and a first overcoat layer OC1 disposed on the gate thin film transistor GIP TFT, the second clock lines SC_CL and SE_CL disposed on the first overcoat layer OC1.

The second clock lines SC_CL and SE_CL may be multi-layer lines including the first electrode 211 and the reflection layer 212 disposed on the first electrode 211, but are not limited thereto. For example, the second clock lines SC_CL and SE_CL may be multi-layer lines formed of the same material as the first electrode 211 and the reflection layer 212 through the same process. Further, the second clock lines SC_CL and SE_CL may be single layer lines formed of the same material as the first electrode 211 through the same process.

Referring to FIG. 11, a second overcoat layer OC2 may be additionally disposed between the first overcoat layer OC1 and the second clock lines SC_CL and SE_CL. When the first overcoat layer OC1 and the second overcoat layer OC2 are disposed on the gate driving unit GIP and the second clock lines SC_CL and SE_CL are disposed on the second overcoat layer OC2, signal interference between the lines of the gate driving unit GIP and the second clock lines SC_CL and SE_CL may be reduced or minimized.

Referring to FIGS. 10 and 11, in the clock line portion CLS2, the second clock lines SC_CL and SE_CL may be disposed on the gate driving unit GIP, and the first clock lines CR_CL may be disposed on another layer, thereby reducing the area where the clock line portion CLS2 are formed in the bezel area. Accordingly, the bezel of the display device may be reduced.

Referring to FIGS. 10 and 11, in a display device according to embodiments of the disclosure, a non-emission area may include a repair line RL disposed on a substrate SUB, a first overcoat layer OC1 disposed on the repair line RL and including a contact hole, a first electrode 211 disposed in the contact hole, and a reflection layer 212 disposed on the first electrode 211, and at least one insulation layer may be disposed between the repair line RL and the first electrode 211.

Referring to FIGS. 10 and 11, when the repair line RL and the first electrode 211 of the subpixel are connected to the welding point WP of the welding repair portion WR using the laser beam LSR, the laser beam LSR may be prevented from being directed to the second electrode 215 which is the cathode electrode by the reflection layer 212 even if the laser beam LSR passes through the first electrode 211 which is the transparent electrode. Therefore, damage to the second electrode, which is the cathode electrode, by the repair laser, may be reduced and the progressive dark spot defect rate may be reduced.

Embodiments of the disclosure described above are briefly described below.

A display device according to embodiments of the disclosure may comprise a substrate SUB including a plurality of subpixels SP1 to SP4, an overcoat layer OC disposed on the substrate SUB and having a recess RC positioned between the subpixels SP1 to SP4, a first electrode 211 disposed to cover an upper surface of the overcoat layer OC and an inclined surface 222 of the recess RC and including a transparent conductive material, a reflection layer 212 disposed on the first electrode 211 on the inclined surface 222 of the recess RC and including a metal or metal alloy, and a bank layer 221 positioned in the recess RC and disposed on the reflection layer 212.

The reflection layer 212 may include a first portion FPO disposed to extend over a portion of an upper surface US of the overcoat layer OC.

The first portion FPO may be disposed to be covered by the bank layer 221.

The first portion FPO may include a protrusion 212a exposed to an outside of the bank layer 221.

The protrusion 212a may be an oxide insulation layer that is an oxide of the metal or metal alloy.

The reflection layer 212 may include a second portion SPO disposed on the inclined surface 222 of the recess RC. A width of the first portion FPO projected onto a plane may be larger than a width of the second portion SPO projected onto a plane.

A width of the first portion FPO emitted on a plane may be smaller than a width of the second portion SPO emitted on a plane.

In the display device according to embodiments of the disclosure, the first electrode 211 may be disposed to be disconnected on a lower surface 223 of the recess RC. The reflection layer 212 may be disposed in an area overlapping the first electrode 211 in the recess RC.

The first electrode 211 may include at least one of indium tin oxide (ITO), indium zinc oxide (IZO) or indium tin zinc oxide (ITZO).

The reflection layer 212 may include any one selected from the group consisting of silver (Ag), aluminum (Al), magnesium (Mg), chromium (Cr), titanium (Ti), nickel (Ni), tungsten (W), gold (Au), tantalum (Ta), copper (Cu), cobalt (Co), iron (Fe), molybdenum (Mo), platinum (Pt), and an alloy thereof.

The display device according to embodiments of the disclosure may include an organic light emitting layer 213 and a second electrode 215 disposed on the first electrode 211 and the bank layer 221.

A display device according to embodiments of the disclosure may comprise a substrate SUB including a display area including a subpixel SP1 to SP4 and a non-display area surrounding the display area, an overcoat layer OC disposed on the substrate SUB and including an upper surface having an X zone and a Z zone and an inclined surface having a Y zone adjacent to the Z zone, an organic light emitting element 213 disposed in the X zone and including a first electrode 211, an organic light emitting layer 213, and a second electrode 215, and a reflection layer disposed in a portion of the Z zone and the Y zone. Where the subpixel emits light, emission widths of the X, Y, and Z zones produced on a plane may have a relationship of X zone>Y zone>Z zone.

The first electrode 211 may be disposed to extend from the X zone to the Z zone and the Y zone.

The display device may further comprise a bank layer BNK on the overcoat layer OC. The bank layer BNK may be disposed to cover one end of the reflection layer 212 in the Z zone.

The non-display area may include a clock line portion CLS2 including first clock lines CR_CL and second clock lines SC_CL and SE_CL disposed on different layers. The second clock lines SC_CL and SE_CL may be multi-layer lines of the first electrode 211 and the reflection layer 212 disposed on the first electrode 211.

The non-display area may further include a gate driving unit GIP. The first clock lines CR_CL may be disposed on the substrate SUB, and the second clock lines SC_CL and SE_CL may be disposed on the gate driving unit GIP.

The overcoat layer OC may be disposed between the gate driving unit GIP and the second clock lines SC_CL and SE_CL.

The display device according to embodiments of the disclosure may comprise a plurality of subpixels SP1 to SP4 including an emission area and a non-emission area and a substrate SUB where a bank layer BNK defining an opening of each of the plurality of subpixels SP1 to SP4 is disposed.

The emission area may include a first overcoat layer OC1 disposed on the substrate SUB, a second overcoat layer OC2 disposed on the first overcoat layer OC1 and positioned in an area corresponding to the opening OPN, and a first electrode 211 disposed on the second overcoat layer OC2.

The non-emission area may include a thin film transistor TFT disposed on the substrate SUB, a first overcoat layer OC1 disposed on the thin film transistor TFT, a first electrode 211 disposed on the first overcoat layer OC1, and a reflection layer 212 disposed on the first electrode 211.

The display device according to embodiments of the disclosure may comprise a clock line portion CLS2 including first clock lines CR_CL and second clock lines SC_CL and SE_CL disposed on different layers.

The second clock lines SC_CL and SE_CL may be multi-layer lines including a first electrode 211 and a reflection layer 212 disposed on the first electrode 211.

The non-emission area may further include a gate driving unit. The gate driving unit may include a gate thin film transistor GIP TFT disposed on the substrate SUB and a first overcoat layer OC1 disposed on the gate thin film transistor GIP TFT.

The first clock lines CR_CL may be disposed on the substrate SUB, and the second clock lines SC_CL and SE_CL may be disposed on the gate driving unit GIP.

A second overcoat layer OC2 may be disposed between the first overcoat layer OC1 and the second clock lines SC_CL and SE_CL.

In a display device according to embodiments of the disclosure, the non-emission area may include a repair line RL disposed on the substrate SUB, the first overcoat layer OC1 disposed on the repair line RL and including a contact hole, and the first electrode 211 disposed in the contact hole and the reflection layer 212 disposed on the first electrode 211, and at least one insulation layer may be disposed between the repair line RL and the first electrode 211.

A display device according to embodiments of the disclosure may comprise a substrate, an overcoat layer disposed on the substrate, the overcoat layer having an upper surface and an inclined side surface extending from the upper surface, a light emitting element having a first electrode on the overcoat layer, a second electrode, and an organic light emitting layer between the first and second electrodes, the first electrode on the upper surface of the overcoat layer and extending over the inclined side surface of the overcoat layer, and a reflection layer on the first electrode at the inclined side surface of the overcoat layer, the reflection layer spaced apart from the organic light emitting layer.

The overcoat layer may include a first overcoat layer and a second overcoat layer on the first overcoat layer, the first electrode may contact an inclined side surface of the second overcoat layer and an upper surface of the second overcoat layer, the inclined side surface of the second overcoat layer may be the inclined side surface of the overcoat layer, and the upper surface of the second overcoat layer may be the upper surface of the overcoat layer.

The display device may further comprise a bank layer on the overcoat layer and adjacent to the light emitting element, the organic light emitting layer may extend over the bank layer, and the second electrode may extend over the light emitting layer at the bank layer.

The display device may further comprise a trench included in the bank layer, the organic light emitting layer may extend over the bank layer and into the trench, and the second electrode may extend over the light emitting layer at the trench.

The trench may not overlap with the reflection layer.

The display device may comprise an X zone, a Y zone and a Z zone. The X zone includes a zone where the upper surface of the overcoat layer contacts the organic light emitting layer, the Y zone includes a zone where the inclined side surface of the overcoat layer is located, and the Z zone is between the X zone and the Y zone, emission widths of the X zone produced as the display device emits light on a plane has greater emission widths than that of the Y zone.

Emission widths of the Y zone produced as the display device emits light on a plane may have greater emission widths than that of the Z zone.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed:

1. A display device, comprising:
a substrate including a plurality of subpixels;
an overcoat layer disposed on the substrate; and having a recess positioned between the subpixels;
a first electrode disposed to cover an upper surface of the overcoat layer and an inclined surface of the recess, the first electrode including a transparent conductive material;
a reflection layer disposed on the first electrode on the inclined surface of the recess, the reflection layer including a metal or metal alloy; and
a bank layer positioned in the recess and disposed on the reflection layer.

2. The display device of claim 1, wherein the reflection layer includes a first portion and a second portion, the first portion of the reflection layer disposed to extend over a portion of the upper surface of the overcoat layer.

3. The display device of claim 2, wherein the first portion of the reflection layer is covered by the bank layer.

4. The display device of claim 2, wherein the first portion of the reflection layer includes a protrusion exposed to an outside of the bank layer.

5. The display device of claim 4, wherein the protrusion is an oxide insulation layer that is an oxide of the metal or metal alloy.

6. The display device of claim 2, wherein the second portion of the reflection layer is on the inclined surface of the recess, and
wherein a width of the first portion projected onto a plane is larger than a width of the second portion projected onto a plane.

7. The display device of claim 2, wherein a width of the first portion projected onto a plane is smaller than a width of the second portion projected onto a plane.

8. The display device of claim 1, wherein the first electrode is disposed to be disconnected at a lower surface of the recess, and
wherein the reflection layer is disposed in an area overlapping the first electrode in the recess.

9. The display device of claim 1, wherein the first electrode includes at least one of indium tin oxide (ITO), indium zinc oxide (IZO), or indium tin zinc oxide (ITZO), and
wherein the reflection layer includes any one selected from the group consisting of silver (Ag), aluminum (Al), magnesium (Mg), chromium (Cr), titanium (Ti), nickel (Ni), tungsten (W), gold (Au), tantalum (Ta), copper (Cu), cobalt (Co), iron (Fe), molybdenum (Mo), platinum (Pt), and an alloy thereof.

10. The display device of claim 1, further comprising an organic light emitting layer and a second electrode disposed on the first electrode and the bank layer.

11. A display device, comprising:
a substrate including a display area including a subpixel and a non-display area adjacent to the display area;
an overcoat layer disposed on the substrate and including an upper surface having an X zone and a Z zone and an inclined surface having a Y zone adjacent to the Z zone;
an organic light emitting element disposed in the X zone and including a first electrode, an organic light emitting layer, and a second electrode; and
a reflection layer disposed in a portion of the Z zone and the Y zone,
wherein when the subpixel emits light, emission widths of the X, Y, and Z zones produced on a plane have a relationship of X zone>Y zone>Z zone.

12. The display device of claim 11, wherein the first electrode is disposed to extend from the X zone to the Z zone and the Y zone.

13. The display device of claim 11, further comprising a bank layer on the overcoat layer,
wherein the bank layer is disposed to cover one end of the reflection layer in the Z zone.

14. The display device of claim 11, wherein the non-display area includes a clock line portion including first clock lines and second clock lines disposed on different layers, and
wherein the second clock lines are multi-layer lines of the first electrode and the reflection layer disposed on the first electrode.

15. The display device of claim 14, wherein the non-display area further includes a gate driving unit,
wherein the first clock lines are disposed on the substrate, and
wherein the second clock lines are disposed on the gate driving unit.

16. The display device of claim 15, wherein the overcoat layer is disposed between the gate driving unit and the second clock lines.

17. A display device, comprising:
a plurality of subpixels including an emission area and a non-emission area; and
a substrate where a bank layer defining an opening of each of the plurality of subpixels is disposed,
wherein the emission area includes:
a first overcoat layer disposed on the substrate;
a second overcoat layer positioned in an area corresponding to the opening and disposed on the first overcoat layer; and
a first electrode disposed on the second overcoat layer, and
wherein the non-emission area includes:
a thin film transistor disposed on the substrate;
the first overcoat layer disposed on the thin film transistor;
the first electrode disposed on the first overcoat layer; and
a reflection layer disposed on the first electrode.

18. The display device of claim 17, wherein the non-emission area includes a clock line portion including first clock lines and second clock lines disposed on different layers, and
wherein the second clock lines are multi-layer lines of the first electrode and the reflection layer disposed on the first electrode.

19. The display device of claim 18, wherein the non-emission area further includes a gate driving unit,
wherein the gate driving unit includes:
a gate thin film transistor disposed on the substrate; and
the first overcoat layer disposed on the gate thin film transistor,
wherein the first clock lines are disposed on the substrate, and
wherein the second clock lines are disposed on the gate driving circuit.

20. The display device of claim 19, wherein the second overcoat layer is disposed between the first overcoat layer and the second clock lines.

21. The display device of claim 17, wherein the non-emission area includes:
a repair line disposed on the substrate;
the first overcoat layer disposed on the repair line and including a contact hole; and
the first electrode disposed in the contact hole and the reflection layer disposed on the first electrode, and
wherein at least one insulation layer is disposed between the repair line and the first electrode.

22. A display device, comprising:
a substrate;
an overcoat layer disposed on the substrate, the overcoat layer having an upper surface and an inclined side surface extending from the upper surface;
a light emitting element having a first electrode on the overcoat layer, a second electrode, and an organic light emitting layer between the first and second electrodes, the first electrode on the upper surface of the overcoat layer and extending over the inclined side surface of the overcoat layer; and
a reflection layer on the first electrode at the inclined side surface of the overcoat layer, the reflection layer spaced apart from the organic light emitting layer.

23. The display device of claim 22, wherein the overcoat layer includes a first overcoat layer and a second overcoat layer on the first overcoat layer,
wherein the first electrode contacts an inclined side surface of the second overcoat layer and an upper surface of the second overcoat layer,
wherein the inclined side surface of the second overcoat layer is the inclined side surface of the overcoat layer, and
wherein the upper surface of the second overcoat layer is the upper surface of the overcoat layer.

24. The display device of claim 22, comprising:
a bank layer on the overcoat layer and adjacent to the light emitting element;
wherein the organic light emitting layer extends over the bank layer, and
wherein the second electrode extends over the light emitting layer at the bank layer.

25. The display device of claim 24, comprising:
a trench included in the bank layer,
wherein the organic light emitting layer extends over the bank layer and into the trench, and
wherein the second electrode extends over the light emitting layer at the trench.

26. The display device of claim 25, wherein the trench does not overlap with the reflection layer.

27. The display device of claim 22, wherein an X zone includes a zone where the upper surface of the overcoat layer contacts the organic light emitting layer, a Y zone includes a zone where the inclined side surface of the overcoat layer is located, and a Z zone is between the X zone and the Y zone,
wherein emission widths of the X zone produced as the display device emits light on a plane has greater emission widths than that of the Y zone.

28. The display device of claim 27, wherein emission widths of the Y zone produced as the display device emits light on a plane has greater emission widths than that of the Z zone.
